(19) United States
(12) Patent Application Publication
(10) Pub. No.: US 2023/0384165 A1
(43) Pub. Date: Nov. 30, 2023

(54) BOLOMETER-TYPE INFRARED DETECTOR AND METHOD FOR MANUFACTURING THE SAME

(71) Applicant: NEC Corporation, Tokyo (JP)

(72) Inventors: Tomo TANAKA, Tokyo (JP); Masahiko ISHIDA, Tokyo (JP); Ryota YUGE, Tokyo (JP)

(73) Assignee: NEC Corporation, Tokyo (JP)

(21) Appl. No.: 18/201,533

(22) Filed: May 24, 2023

(30) Foreign Application Priority Data
May 27, 2022 (JP) 2022-086633

(51) Int. Cl. G01J 5/20; H10N 19/00

(52) U.S. Cl. CPC G01J 5/20; H10N 19/00; G01J 2005/202

(57) ABSTRACT

Disclosed is a bolometer type infrared detector comprising: a substrate, a bolometer film comprising semiconducting carbon nanotubes, and two electrodes spaced from each other and connected to the bolometer film, wherein at least one of the two electrodes is formed of a metal alloy comprising at least two metals selected from the group consisting of Li, Be, Al, Ti, V, Cr, Mn, Fe, Co, Ni, Cu, Zn, Y, Zr, Nb, Mo, Ru, Rh, Pd, Ag, In, Sn, Sb, Ba, La, Hf, Ta, Ir, Pt, Au, and Bi.

This application is based upon and claims the benefit of priority from Japanese patent application No. 2022-086633, filed on May 27, 2022, the disclosure of which is incorporated herein in its entirety by reference.

### TECHNICAL FIELD

The present invention relates to a bolometer type infrared detector and a method for manufacturing the same.

### BACKGROUND ART

Infrared sensors have a very wide range of applications such as not only monitoring cameras for security, but also thermography for human body, in-vehicle cameras, and inspection of structures, foods, and the like, and are thus actively used in industrial applications in recent years. In particular, development of a low-cost and high-performance uncooled infrared sensor capable of obtaining biological information in cooperation with IoT (Internet of Things) is expected. In conventional uncooled infrared sensors, VOx (vanadium oxide) has been mainly used in the bolometer unit, but the problem thereof is that the process cost is high because heat treatment under vacuum is required and the temperature coefficient resistance (TCR) thereof is low (about −2.0%/K).

In order to improve TCR, a material with large resistance-change vs temperature-change and high conductivity is required. Hence, it is expected to use semiconducting single-walled carbon nanotubes which have large bandgap and carrier mobility to the bolometer part. In addition, since carbon nanotubes are chemically stable, an inexpensive device fabrication processes such as printing technology can be used, and thus the realization of low-cost and high-performance infrared sensors is highly expected.

For example, Patent Document 1 proposed to apply typical single-walled carbon nanotubes to a bolometer unit, and produce a bolometer by a low-cost thin film process in which a dispersion liquid is prepared by mixing single-walled carbon nanotubes in an organic solvent utilizing their chemical stability and then is applied on an electrode. In this case, TCR is successfully improved to about −1.8%/K by subjecting single-walled carbon nanotubes to annealing treatment in the air.

Since single-walled carbon nanotubes usually contain semiconducting carbon nanotubes and metallic-type carbon nanotubes in a ratio of 2:1, there is a problem that the separation of semiconducting carbon nanotubes and metallic-type carbon nanotubes is necessary. In Patent Document 2, since metallic and semiconducting components are present in a mixed state in single-walled carbon nanotubes, semiconducting single-walled carbon nanotubes of uniform chirality are extracted using an ionic surfactant and applied to the bolometer unit, and TCR of −2.6%/K is thereby successfully achieved.

### CITATION LIST

### Patent Literature

Patent Document 1: WO 2012/049801
Patent Document 2: Japanese Patent Laid-Open No. 2015-49207

### SUMMARY OF INVENTION

### Technical Problem

However, in the carbon nanotube thin film used for the infrared sensor described in Patent Document 1, since many metallic carbon nanotubes are present in a mixed state in carbon nanotubes, TCR is low at room temperature and the improvement of the performance of the infrared sensor is limited.

The TCR value of the infrared sensor using semiconducting carbon nanotubes described in Patent Document 2 is not sufficient for high sensitivity, and further improvement of the carbon nanotube film is necessary.

In view of the above problems, an object of the present invention is to provide a bolometer type infrared sensor capable of realizing a high TCR value and to provide a method of manufacturing the same.

### Solution to Problem

One aspect of the present invention relates to a bolometer type infrared detector comprising: a substrate, a bolometer film comprising semiconducting carbon nanotubes, and two electrodes spaced from each other and connected to the bolometer film, wherein at least one of the two electrodes is formed of a metal alloy comprising at least two metals selected from the group consisting of Li, Be, Al, Ti, V, Cr, Mn, Fe, Co, Ni, Cu, Zn, Y, Zr, Nb, Mo, Ru, Rh, Pd, Ag, In, Sn, Sb, Ba, La, Hf, Ta, Ir, Pt, Au, and Bi.

One aspect of the present invention relates to a method of manufacturing a bolometer type infrared detector, the method comprising: providing a substrate, forming a bolometer film comprising semiconducting carbon nanotubes, and forming two electrodes so that the two electrodes are spaced from each other and connected to the bolometer film, wherein at least one of the two electrodes is formed of a metal alloy comprising at least two metals selected from the group consisting of Li, Be, Al, Ti, V, Cr, Mn, Fe, Co, Ni, Cu, Zn, Y, Zr, Nb, Mo, Ru, Rh, Pd, Ag, In, Sn, Sb, Ba, La, Hf, Ta, Ir, Pt, Au, and Bi.

### Advantageous Effect of Invention

According to the present invention, it is possible to provide a bolometer detector capable of obtaining a high TCR value.

### BRIEF DESCRIPTION OF DRAWINGS

FIG. 1 is a plan view of a bolometer element (device) according to an embodiment of the present invention.

FIG. 2A is a graph showing the relationship between voltage and current (293K) and FIG. 2B is a graph showing the relationship between voltage and TCR (293K-303K) for a device with near-linear IV characteristics.

FIG. 3A is a graph showing the relationship between voltage and current (293K) and FIG. 3B is a graph the relationship between voltage and TCR (293K-303K) for a device with non-linear IV characteristics.

FIG. 4 is a vertical sectional front view showing the cell structure of a bolometer according to an embodiment of the present invention.

FIG. 5 is a vertical sectional front view showing the cell structure of a bolometer according to an embodiment of the present invention.

FIG. 6 is a plan view showing the structure of a bolometer array according to an embodiment of the present invention.

FIG. 7 is a vertical sectional front view showing the cell structure of a bolometer according to an embodiment of the present invention.

FIG. 8A to 8D is a vertical sectional front view showing a method for manufacturing a bolometer according to an embodiment of the present invention.

FIG. 9A to 9C is a process chart showing a method for manufacturing a bolometer array according to an embodiment of the present invention.

FIG. 10 is a plan view showing the structure of a bolometer array according to an embodiment of the present invention.

FIG. 11A is a vertical sectional front view showing the cell structure and FIG. 11B is a plan view showing the structure of an array of a bolometer according to an embodiment of the present invention.

FIG. 12 is a graph showing binary alloy compositions predicted by machine learning model.

FIG. 13 is a graph showing binary alloy compositions predicted by machine learning model.

FIG. 14 is a graph showing binary alloy compositions predicted by machine learning model.

FIG. 15 is a graph showing binary alloy compositions predicted by machine learning model.

### DESCRIPTION OF EMBODIMENTS

The present inventors revealed that in a bolometer type detector using a bolometer film containing carbon nanotubes, the condition of the connection between carbon nanotubes and contact electrodes extremely affects TCR, and that in particular, as a material of the contact electrode contacting the carbon nanotube, the use of an alloy of two or more metals selected from the group consisting of Li, Be, Al, Ti, V, Cr, Mn, Fe, Co, Ni, Cu, Zn, Y, Zr, Nb, Mo, Ru, Rh, Pd, Ag, In, Sn, Sb, Ba, La, Hf, Ta, Ir, Pt, Au, and Bi gives higher TCR.

A configuration of a bolometer type infrared detector having a contact electrode of the present embodiment will be described below.

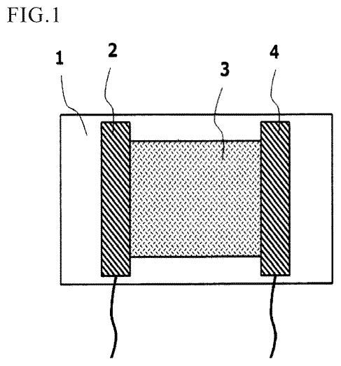

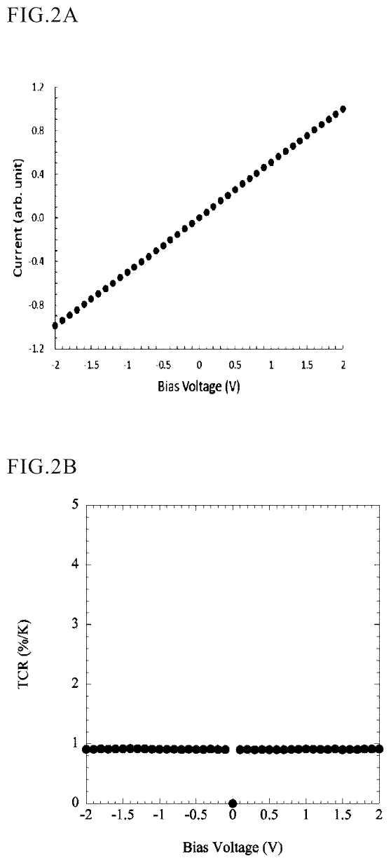

As described in FIG. 1, the bolometer type infrared detector of the present embodiment includes at least a substrate 1, a bolometer film 3 (CNT film) formed on the substrate 1, and two contact electrodes 2, 4 provided in contact with the bolometer film 3 (CNT film). Conventionally, in CNT transistors and the like, metals such as Au, Ti, and Pt, which provide good ohmic contact, are used as materials for contact electrodes. In the current-voltage characteristics (IV characteristics) when an ohmic junction is formed between the CNT film and the contact electrode, generally as shown on the left side of FIG. 2, the IV curve for positive bias voltage and the IV curve for negative bias voltage are symmetrical, and the TCR is typically constant independent of voltage as shown in right side of FIG. 2.

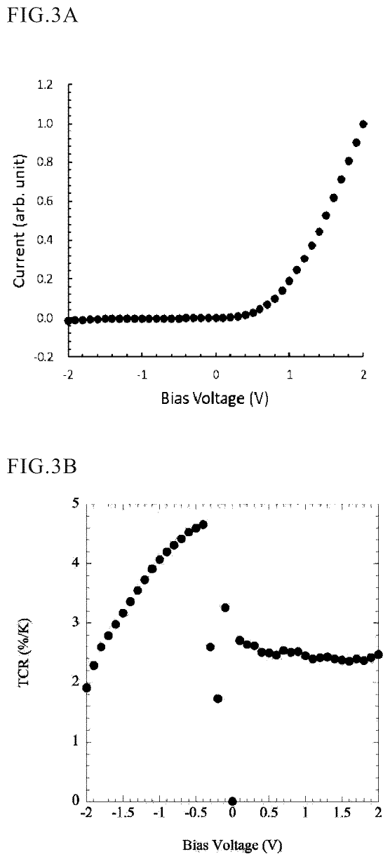

In contrast, the present inventor found that if the material of the contact electrode is selected so that the connection between the CNT film and the contact electrode becomes a Schottky junction, IV characteristic shows an asymmetric curve between a positive bias voltage and a negative bias voltage region as shown in FIG. 3 left, and the TCR thereof changes depending on the voltage, and for example, a large TCR is obtained at the negative bias voltage side at which current flow is less. The junction of a CNT film and a contact electrode is intricately affected by, in addition to the work function of the material, the interface state (surface state), and the like, but it has been revealed that if an alloy obtained by combining two or more metals is used, an appropriate adjustment can be possible so as to obtain a large TCR.

### (Contact Electrode)

It is sufficient that at least one of the two contact electrodes connected to the bolometer film should be made of an alloy, but it is generally preferred that both electrodes are made of an alloy. In addition, the same or different alloy may be used for the two contact electrodes.

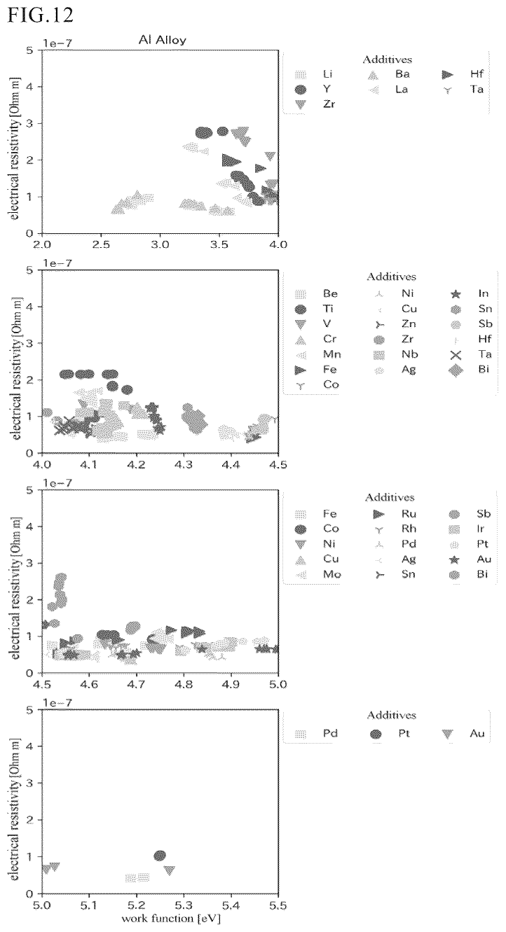

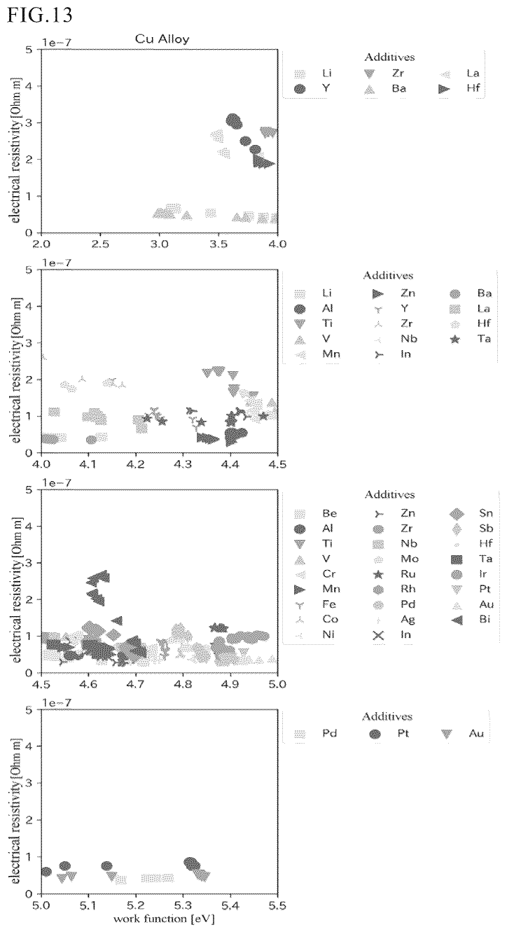

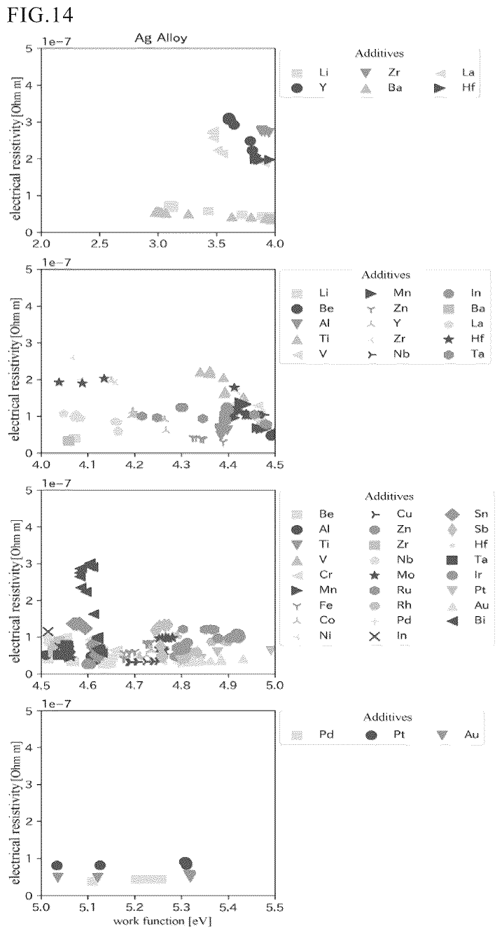

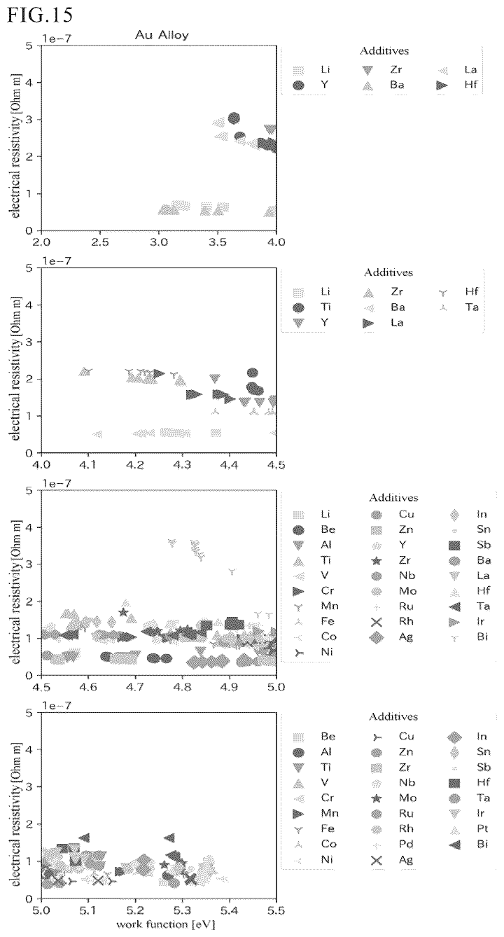

The inventors identified alloy compositions suitable for use in the electrodes of the bolometer type infrared detector of this embodiment by building a machine learning model such as Random Forest, MLPregressor, sklern_fabn using the data of work function and electrical resistivity obtained from experiments and simulations as target variables for calculation, and predicting the compositions of binary alloys having favourable values for both target variables (see, FIGS. 12 to 15).

Specifically, alloys that form the electrodes preferably contain two or more metals selected from Li, Be, Al, Ti, V, Cr, Mn, Fe, Co, Ni, Cu, Zn, Y, Zr, Nb, Mo, Ru, Rh, Pd, Ag, In, Sn, Sb, Ba, La, Hf, Ta, Ir, Pt, Au, and Bi, and more preferably contain at least one metal selected from Al, Cu, Ag, and Au.

The composition of the alloys is not particularly limited, but the compositions for each electrode may be determined so as to form a junction condition in which the Schottky barrier height and the like is controlled at each of the two electrodes.

For the alloy used for the electrode of the bolometer type infrared detector, a low electrical resistivity is also desired as well as a suitable work function. Examples of alloys that meet the desired work function and electrical resistivity are given below.

### <Alloy Containing Al>

For the purpose of making the electrical resistivity 500 nΩm or less, preferably 100 nΩm or less, and the work function of the alloy higher than 5.0 eV, the alloy, in combination with Al, preferably contains at least one metal selected from Pd, Pt, and Au.

For the purpose of making the electrical resistivity 500 nΩm or less, and the work function of the alloy from 4.5 eV to 5.0 eV, the alloy, in combination with Al, preferably contains at least one metal selected from Fe, Co, Ni, Cu, Mo, Ru, Rh, Pd, Ag, Sn, Sb, Ir, Pt, Au, and Bi. More preferably, for the purpose of making an electrical resistivity of 100 nΩm or less, and the work function of the alloy from 4.5 eV to 5.0 eV, the alloy, in combination with Al, preferably contains at least one metal selected from Fe, Co, Ni, Cu, Mo, Ru, Rh, Pd, Ag, Sb, Ir, Pt and Au.

Similarly, for the purpose of making the electrical resistivity of 500 nΩm or less, preferably 100 nΩm or less, and the work function of the alloy from 4.0 eV to 4.5 eV, the alloy, in combination with Al, preferably contains at least one selected from Be, Ti, V, Cr, Mn, Fe, Co, Ni, Cu, Zn, Zr, Nb, Ag, In, Sn, Sb, Hf, Ta, and Bi.

Similarly, for the purpose of making the electrical resistivity of 500 nΩm or less, preferably 100 nΩm or less, and the work function of the alloy from 4.5 eV to 5.0 eV, the alloy, in combination with Al, preferably contains at least one selected from Li, Y, Zr, Ba, La, Hf, and Ta.

### <Alloy Containing Cu>

For the purpose of making the electrical resistivity 500 nΩm or less, preferably 100 nΩm or less, and the work function of the alloy higher than 5.0 eV, the alloy, in combination with Cu, preferably contains at least one metal selected from Pd, Pt, and Au.

For the purpose of making the electrical resistivity of 500 nΩm or less, preferably 100 nΩm or less, and the work function of the alloy from 4.5 eV to 5.0 eV, the alloy, in combination with Cu, preferably contains at least one selected from Be, Al, Ti, V, Cr, Mn, Fe, Co, Ni, Zn, Zr, Nb, Mo, Ru, Rh, Pd, Ag, In, Sn, Sb, Hf, Ta, Ir, Pt, Au, and Bi.

Similarly, for the purpose of making the electrical resistivity of 500 nΩm or less, and the work function of the alloy from 4.0 eV to 4.5 eV, the alloy, in combination with Cu, preferably contains at least one selected from, Li, Al, Ti, V, Mn, Zn, Y, Zr, Nb, In, Ba, La, Hf, Ta. More preferably, for the purpose of making the electrical resistivity of 100 nΩm or less, and the work function of the alloy from 4.0 eV to 4.5 eV, the alloy, in combination with Cu, preferably contains at least one selected from, Li, Al, Mn, Zn, Y, Nb, In, Ba, La, and Ta.

Similarly, for the purpose of making the electrical resistivity of 500 nΩm or less, and the work function of the alloy lower than 4.0 eV, the alloy, in combination with Cu, preferably contains at least one selected from Li, Y, Zr, Ba, La, and Hf. More preferably, for the purpose of making the electrical resistivity of 100 nΩm or less, and the work function of the alloy lower than 4.0 eV, the alloy, in combination with Cu, preferably contains at least one selected from Li, and Ba.

### <Alloy Containing Ag>

For the purpose of making the electrical resistivity 500 nΩm or less, preferably 100 nΩm or less, and the work function of the alloy higher than 5.0 eV, the alloy, in combination with Ag, preferably contains at least one metal selected from Pd, Pt, and Au.

For the purpose of making the electrical resistivity of 500 nΩm or less, preferably 100 nΩm or less, and the work function of the alloy from 4.5 eV to 5.0 eV, the alloy, in combination with Ag, preferably contains at least one selected from Be, Al, Ti, V, Cr, Mn, Fe, Co, Ni, Cu, Zn, Zr, Nb, Mo, Ru, Rh, Pd, In, Sn, Sb, Hf, Ta, Ir, Pt, Au, and Bi.

Similarly, for the purpose of making the electrical resistivity of 500 nΩm or less, and the work function of the alloy from 4.0 eV to 4.5 eV, the alloy, in combination with Ag, preferably contains at least one selected from, Li, Be, Al, Ti, V, Mn, Zn, Y, Zr, Nb, In, Ba, La, Hf, and Ta. More preferably, for the purpose of making the electrical resistivity of 100 nΩm or less, and the work function of the alloy from 4.0 eV to 4.5 eV, the alloy, in combination with Ag, preferably contains at least one selected from, Li, Be, Al, Ti, Mn, Zn, Y, Zr, Ba, La, Hf, and Ta.

Similarly, for the purpose of making the electrical resistivity of 500 nΩm or less, and the work function of the alloy lower than 4.0 eV, the alloy, in combination with Ag, preferably contains at least one selected from Li, Y, Zr, Ba, La, and Hf. More preferably, for the purpose of making the electrical resistivity of 100 nΩm or less, and the work function of the alloy lower than 4.0 eV, the alloy, in combination with Ag, preferably contains at least one selected from Li, and Ba.

### <Alloy Containing Au>

For the purpose of making the electrical resistivity 500 nΩm or less, and the work function of the alloy higher than 5.0 eV, the alloy, in combination with Au, preferably contains at least one metal selected from Be, Al, Ti, V, Cr, Mn, Fe, Co, Ni, Cu, Zn, Zr, Nb, Mo, Ru, Rh, Pd, Ag, In, Sn, Sb, Hf, Ta, Ir, Pt, and Bi. More preferably, for the purpose of making an electrical resistivity of 100 nΩm or less, and the work function of the alloy higher than 5.0 eV, the alloy, in combination with Au, preferably contains at least one metal selected from Be, Al, Ti, V, Cr, Mn, Fe, Co, Ni, Cu, Zn, Zr, Nb, Mo, Ru, Rh, Pd, Ag, In, Sn, Sb, Ta, Ir, and Pt.

For the purpose of making the electrical resistivity 500 nΩm or less, and the work function of the alloy from 4.5 eV to 5.0 eV, the alloy, in combination with Au, preferably contains at least one metal selected from Li, Be, Al, Ti, V, Cr, Mn, Fe, Co, Ni, Cu, Zn, Y, Zr, Nb, Mo, Ru, Rh, Ag, In, Sn, Sb, Ba, La, Hf, Ta, Ir, and Bi. More preferably, for the purpose of making an electrical resistivity of 100 nΩm or less, and the work function of the alloy from 4.5 eV to 5.0 eV, the alloy, in combination with Au, preferably contains at least one metal selected from Li, Be, Al, V, Cr, Mn, Fe, Ni, Cu, Zn, Y, Nb, Mo, Rh, Ag, In, and Ba.

Similarly, for the purpose of making the electrical resistivity of 500 nΩm or less, and the work function of the alloy from 4.0 eV to 4.5 eV, the alloy, in combination with Au, preferably contains at least one selected from Li, Ti, Y, Zr, Ba, La, Hf, and Ta. More preferably, for the purpose of making an electrical resistivity of 100 nΩm or less, and the work function of the alloy from 4.0 eV to 4.5 eV, the alloy, in combination with Au, preferably contains at least one metal selected from Li, and Ba.

Similarly, for the purpose of making the electrical resistivity of 500 nΩm or less, and the work function of the alloy lower than 4.0 eV, the alloy, in combination with Au, preferably contains at least one selected from Li, Y, Zr, Ba, La, and Hf. More preferably, for the purpose of making the electrical resistivity of 100 nΩm or less, and the work function of the alloy lower than 4.0 eV, the alloy, in combination with Au, preferably contains at least one selected from Li, and Ba.

In one embodiment, the electrical resistivity of the alloy material is 500 nΩm or less, preferably 400 nΩm or less, more preferably 300 nΩm or less, still more preferably 200 nΩm or less, particularly preferably 100 nΩm or less.

In addition to electrical resistivity and work function, the composition of the alloy may be optimized so as to satisfy the purpose of controlling the thickness of the tunnel barrier by forming a surface oxide film, the purpose of optimizing the heat diffusion from the light receiving part to the electrode material, and the purpose of controlling the temperature dependence of resistivity, and the like.

The size and thickness of the contact electrode are not particularly limited, but the thickness is preferably 10 nm to 1 mm, more preferably 50 nm to 1 μm.

The two contact electrodes are formed such that they are spaced apart from each other, and the distance between the contact electrodes is preferably 1 μm to 500 μm, and for miniaturization, it is more preferably 5 to 200 μm. When the distance is 5 μm or more, the deterioration of the characteristics of TCR can be suppressed, even in such a case that a small amount of metallic carbon nanotubes are contained. In addition, the distance of 500 μm or less is advantageous when the infrared sensor is applied to an image sensor by two-dimensionally arraying the infrared sensors.

The method of forming the contact electrode is not particularly limited, but it may be formed by simultaneous vapor deposition, simultaneous sputtering, a printing method, or the like, or a pre-formed alloy film or the like may be used. The contact electrode may be formed after the bolometer film is formed on the substrate as shown in FIG. 1, or the bolometer film may be formed after the contact electrode is formed on the substrate.

### (Bolometer Film)

In the bolometer type infrared detector of this embodiment, a carbon nanotube layer containing semiconducting carbon nanotubes is used.

The carbon nanotube film (CNT film) as a bolometer film is a thin film composed of a plurality of carbon nanotubes forming conductive paths which electrically connect the two contact electrodes. Carbon nanotubes preferably form a network-like structure or the like, and preferably form a three-dimensional network structure because aggregation is less likely to occur and uniform conductive paths can be obtained.

In the network of the carbon nanotubes, the carbon nanotubes may be aligned or not aligned, but preferably aligned to some extent.

As the carbon nanotubes, single-walled, double-walled, and multi-walled carbon nanotubes may be used, but when semiconducting carbon nanotubes are separated, single-walled or few-walled (for example, double-walled or triple-walled) carbon nanotubes are preferred, and single-walled carbon nanotubes are more preferred. The carbon nanotubes preferably comprise single-walled carbon nanotubes in an amount of 80% by mass or more, and more preferably 90% by mass or more (including 100% by mass).

The diameter of the carbon nanotubes is preferably from 0.6 to 1.5 nm, more preferably 0.6 nm to 1.2 nm, and further preferably 0.7 to 1.1 nm, from the viewpoint of increasing the band gap to improve TCR. In one embodiment, the diameter of 1 nm or less may be particularly preferred in some cases. When the diameter is 0.6 nm or more, the manufacture of carbon nanotubes becomes much easier. When the diameter is 1.5 nm or less, the band gap is easily maintained in an appropriate range and a high TCR can be obtained.

As used herein, the diameter of the carbon nanotubes means that when the carbon nanotube film is observed using an atomic force microscope (AFM) and the diameter thereof is measured at about 100 positions, 60% or more, preferably 70% or more, optionally preferably 80% or more, more preferably 100% thereof is within a range of 0.6 to 1.5 nm. It is preferred that 60% or more, preferably 70% or more, optionally preferably 80% or more, and more preferably 100% thereof be within a range of 0.6 to 1.2 nm, and further preferably within a range of 0.7 to 1.1 nm. In one embodiment, 60% or more, preferably 70% or more, optionally preferably 80% or more, and more preferably 100% thereof is within a range of 0.6 to 1 nm.

The length of the carbon nanotubes is preferably from 100 nm to 5 μm because dispersion is easy and application properties are excellent. Also, from the viewpoint of conductivity of the carbon nanotubes, the length is preferably 100 nm or more. When the length is 5 μm or less, aggregation at the time of forming a layer is easily suppressed. The length of the carbon nanotubes is more preferably 500 nm to 3 μm, and further preferably 700 nm to 1.5 μm.

As used herein, the length of the carbon nanotubes means that, when at least 100 carbon nanotubes are observed using an atomic force microscope (AFM) and enumerated to measure the distribution of the length of the carbon nanotubes, 60% or more, preferably 70% or more, optionally preferably 80% or more, and more preferably 100% thereof is within a range of 100 nm to 5 μm. It is preferred that 60% or more, preferably 70% or more, optionally preferably 80% or more, and more preferably 100% thereof be within a range of 500 nm to 3 μm, and it is more preferred that 60% or more, preferably 70% or more, optionally preferably 80% or more, and more preferably 100% thereof be within a range of 700 nm to 1.5 μm.

When the diameter and length of the carbon nanotubes are within the above range, the influence of semiconductive properties becomes large and a large current value can also be obtained, and thus, a high TCR value is likely to be obtained when the carbon nanotubes are used as a bolometer film.

For the bolometer film, semiconducting carbon nanotubes having a large band gap and carrier mobility are preferably used. The content of the semiconducting carbon nanotubes, preferably single-walled semiconducting carbon nanotubes in carbon nanotubes is generally 67% by mass or more, more preferably 70% by mass or more, particularly preferably 80% by mass or more, and in particular, preferably 90% by mass or more, more preferably 95% by mass or more, and further preferably 99% by mass or more (the upper limit may be 100% by mass).

The thickness of the bolometer film is not limited, in the range of, for example, 1 nm or more, for example a few nm to 10 μm, preferably 10 nm to 10 μm, more preferably 50 nm to 1 μm. In one embodiment, it is preferably 20 nm to 500 nm, more preferably 50 nm to 200 nm or more.

When the thickness of the bolometer film is 1 nm or more, a good light absorption rate can be achieved.

When the thickness of the carbon nanotube film is 10 nm or more, preferably nm or more, the element structure can be made simpler because an adequate light absorption rate is obtained even without comprising a light reflection layer or a light absorbing material layer.

In addition, from the view point of simplifying the manufacturing method, it is preferred that the thickness of the bolometer film is 1 μm or less, preferably 500 nm or less. Also, when the bolometer film is too thick, the contact electrode that is formed thereon by vapor deposition and the like may not fully contact the carbon nanotubes at the bottom side of the bolometer film, and the effective resistance value becomes higher, but when the thickness is within the above range, increase of the resistance value can be suppressed.

Also, when the thickness of the bolometer film is in the range of 10 nm to 1 μm as described above, it is also preferable that printing techniques can be suitably applied to the manufacturing method of the bolometer film.

Also, in the case of comprising a light reflection layer or a light absorbing material layer, it is also possible to make the bolometer film thinner than the above range in order to further simplify the manufacturing process and improve the resistance value.

The thickness of the bolometer film can be determined as an average value of the thickness of the carbon nanotube film measured at arbitrary 10 positions.

The density of the bolometer film is, for example, 0.3 g/cm³ or more, preferably 0.8 g/cm³ or more, more preferably 1.1 g/cm³ or more. The upper limit thereof is not particularly limited, but can be the upper limit of the true density of the carbon nanotube used (for example, about 1.4 g/cm³).

When the density of the bolometer film is 0.3 g/cm³ or more, a good light absorbing rate can be achieved.

When the density of the bolometer film is 0.5 g/cm³ or more, it is preferred that the element structure can be simplified because an adequate light absorption rate is obtained even without comprising a light reflection layer or a light absorbing layer.

Also, when a light reflection layer or a light absorbing material layer is comprised, the density of the bolometer film of lower than the above-described density may be appropriately employed.

The density of the bolometer film can be calculated from weight, area, and the thickness obtained as above of the carbon nanotube film.

In addition to the above-mentioned components described above, negative thermal expansion materials described later, ionic conductors (surfactants, ammonium salts, inorganic salts), resins, organic binding agents, and the like may also be appropriately used in the bolometer film.

The content of carbon nanotubes in the bolometer film can be selected appropriately, and preferably more than 0.1% by mass or more based on the total mass of the bolometer film is effective, more preferably 1% by mass or more is effective, for example 30% by mass, and even 50% by mass or more may be preferred, and in some cases 60% by mass or more may be preferred.

An example of a method for manufacturing a carbon nanotube film is described in detail below.

A carbon nanotube film can be formed using, for example, a carbon nanotube dispersion liquid comprising carbon nanotubes and a nonionic surfactant. From the carbon nanotubes, surface functional groups and impurities such as amorphous carbon, catalysts, and the like may be removed by performing a heat treatment under an inert atmosphere, in a vacuum. The heat treatment temperature may be appropriately selected and is preferably 800 to 2000° C., and more preferably 800 to 1200° C.

The nonionic surfactant may be appropriately selected, and it is preferred to use nonionic surfactants constituted by a hydrophilic portion which is not ionized and a hydrophobic portion such as an alkyl chain, for example, nonionic surfactants having a polyethylene glycol structure exemplified by polyoxyethylene alkyl ethers, and alkyl glucoside based nonionic surfactants, singly or in combination. As such a nonionic surfactant, polyoxyethylene alkyl ether represented by Formula (1) is preferably used. In addition, the alkyl moiety may have one or a plurality of unsaturated bonds.

CₙH₂ₙ₊₁(OCH₂CH₂)ₘOH (1)

wherein, n=preferably 12 to 18, and m=10 to 100, and preferably 20 to 100.

In particular, a nonionic surfactant specified by polyoxyethylene (n) alkyl ether (wherein n=20 or more and 100 or less, and the alkyl chain length is C12 or more and C18 or less) such as polyoxyethylene (23) lauryl ether, polyoxyethylene (20) cetyl ether, polyoxyethylene (20) stearyl ether, polyoxyethylene (10) oleyl ether, polyoxyethylene (10) cetyl ether, polyoxyethylene (10) stearyl ether, polyoxyethylene (20) oleyl ether, polyoxyethylene (100) stearyl ether is more preferred. In addition, N,N-bis[3-(D-gluconamido)propyl]deoxycholamide, n-dodecyl-D-maltoside, octyl-D-glucopyranoside, and digitonin may also be used.

As the nonionic surfactant, polyoxyethylene sorbitan monostearate (molecular formula: C₆₄H₁₂₆O₂₆, trade name: Tween 60, manufactured by Sigma-Aldrich, etc.), polyoxyethylene sorbitan trioleate (molecular formula: C₂₄H₄₄O₆, trade name: Tween 85, manufactured by Sigma-Aldrich, etc.), octylphenol ethoxylate (molecular formula: C₁₄H₂₂O(C₂H₄O)ₙ, n=1 to 10, trade name: Triton X-100, manufactured by Sigma-Aldrich, etc.), polyoxyethylene (40) isooctylphenyl ether (molecular formula: C₈H₁₇C₆H₄₀(CH₂CH₂₀)₄₀H, trade name: Triton X-405, manufactured by Sigma-Aldrich, etc.), poloxamer (molecular formula: C₅H₁₀O₂, trade name: Pluronic, manufactured by Sigma-Aldrich, etc.), polyvinyl pyrrolidone (molecular formula: (C₆H₉NO)ₙ, n=5 to 100, manufactured by Sigma-Aldrich, etc.) and the like may be used.

The method for obtaining a dispersion solution of carbon nanotubes is not particularly limited, and conventionally known methods can be applied. For example, a carbon nanotube mixture, a dispersion medium, and a nonionic surfactant are mixed to prepare a solution containing carbon nanotubes, and this solution is subjected to sonication to disperse the carbon nanotubes, thereby preparing a carbon nanotube dispersion liquid (micelle dispersion solution). The dispersion medium is not particularly limited, as long as it is a solvent that allows carbon nanotubes to disperse and suspend during the separation step, and for example, water, heavy water, an organic solvent, an ionic liquid, or a mixture thereof may be used, and water and heavy water are preferred. In addition to or instead of the sonication mentioned above, a technique of dispersing carbon nanotubes by a mechanical shear force may be used. The mechanical shearing may be performed in a gas phase. In a micelle dispersion aqueous solution of the carbon nanotubes and the nonionic surfactant, the carbon nanotubes are preferably in an isolated state. Thus, if necessary, bundles, amorphous carbon, impurity catalysts, and the like may be removed using an ultracentrifugation treatment. During the dispersion treatment, the carbon nanotubes can be cut, and the length thereof can be controlled by changing the grinding conditions of the carbon nanotubes, ultrasonic output, ultrasonic treatment time, and the like. For example, the aggregate size can be controlled by grinding the untreated carbon nanotubes using tweezers, a ball mill, or the like. After these treatments, the length can be controlled to 100 nm to 5 μm using an ultrasonic homogenizer by setting the output to 40 to 600 W, optionally 100 to 550 W, 20 to 100 kHz, the treatment time to 1 to 5 hours, preferably up to 3 hours. When the treatment time is shorter than 1 hour, the carbon nanotubes may be hardly dispersible depending on the conditions, and may remain almost the original length in some cases. From the viewpoint of shortening the dispersion treatment time and reducing the cost, the treatment time is preferably 3 hours or less. The present embodiment may also have the advantage of ease of adjustment of cutting due to use of a nonionic surfactant. In addition, it has the advantage of containing no ionic surfactant which is difficult to be removed.

Dispersion and cutting of the carbon nanotubes generate a surface functional group at the surface or the end of the carbon nanotube. Functional groups such as carboxyl group, carbonyl group, and hydroxyl group are generated. When the treatment is performed in a liquid phase, a carboxyl group and a hydroxyl group are generated, and when the treatment is performed in a gas phase, a carbonyl group is generated.

The concentration of the surfactant in the liquid comprising heavy water or water and a surfactant, preferably a nonionic surfactant mentioned above is preferably from the critical micelle concentration to 10% by mass, and more preferably from the critical micelle concentration to 3% by mass. The concentration less than the critical micelle concentration is not preferred because dispersion is impossible. When the concentration is 10% by mass or less, a sufficient density of carbon nanotubes can be applied after separation, while reducing the amount of surfactant. As used herein, the critical micelle concentration (CMC) refers to the concentration serving as an inflection point of the surface tension measured by, for example, changing the concentration of an aqueous surfactant solution using a surface tensiometer such as a Wilhelmy surface tensiometer at a constant temperature. As used herein, the “critical micelle concentration” is a value under atmospheric pressure at 25° C.

The concentration of the carbon nanotubes in the above cutting and dispersion step (the weight of the carbon nanotubes/(the total weight of the carbon nanotubes, the dispersion medium and the surfactant)×100) is not particularly limited, and for example, may be 0.0003 to 10% by mass, preferably 0.001 to 3% by mass, and more preferably 0.003 to 0.3% by mass.

The dispersion liquid obtained through the aforementioned cutting and dispersion step may be used as it is in the separation step mentioned below, or steps such as concentration and dilution may be performed before the separation step.

Separation of the carbon nanotubes can be performed by, for example, the electric-field-induced layer formation method (ELF method: see, for example, K. Ihara et al. J. Phys. Chem. C. 2011, 115, 22827 to 22832 and Japanese Patent No. 5717233, which are incorporated herein by reference). One example of the separation method using the ELF method will be described. Carbon nanotubes, preferably single-walled carbon nanotubes are dispersed by a nonionic surfactant, and the dispersion liquid is put into a vertical separation apparatus, and then a voltage is applied to the electrodes arranged above and below, so that the carbon nanotubes are separated by free flow electrophoresis. The mechanism of separation can be inferred as follows for example. When the carbon nanotubes are dispersed by the nonionic surfactant, the micelle of the semiconducting carbon nanotubes has a negative zeta potential, whereas the micelle of the metallic carbon nanotubes has an opposite (positive) zeta potential (in recent years, it is considered that the metallic carbon nanotubes have a slightly negative zeta potential or are barely charged). Thus, when an electric field is applied to the carbon nanotube dispersion liquid, the micelle of the semiconducting carbon nanotubes is electrophoresed toward the anode (+) direction, and the micelle of the metallic carbon nanotubes is electrophoresed toward the cathode (−) direction by the difference between the zeta potentials, and the like. Eventually, the layer in which the semiconducting carbon nanotubes are concentrated is formed near the anode, and the layer in which the metallic carbon nanotubes are concentrated is formed near the cathode in the separation tank. The voltage for separation may be appropriately set in consideration of the composition of the dispersion medium, the charge amount of carbon nanotubes, and the like, and is preferably 1 V or more and 200 V or less, and more preferably 10 V or more and 200 V or less. It is preferably 100 V or more from the viewpoint of shortening the time for the separation step. It is preferably 200 V or less from the viewpoint of suppressing the generation of bubbles during separation and maintaining the separation efficiency. The purity is improved by repeating separation. The same separation procedure may be performed by resetting the dispersion liquid after separation to the initial concentration. As a result, the purity can be further increased.

Through the aforementioned dispersion and cutting step and separation step of the carbon nanotubes, a dispersion liquid in which the semiconducting carbon nanotubes having the desired diameter and length are concentrated can be obtained. As used herein, the carbon nanotube dispersion liquid in which semiconducting carbon nanotubes are concentrated may be referred to as the “semiconducting carbon nanotube dispersion liquid”. The semiconducting carbon nanotube dispersion liquid obtained by the separation step comprises semiconducting carbon nanotubes generally 67% by mass or more, preferably 70% by mass or more, more preferably 80% by mass or more in the total amount of carbon nanotubes, and it is particularly preferably 90% by mass or more, more preferably 95% by mass or more, further preferably 99% by mass or more (the upper limit may be 100% by mass). The separation tendency of the metallic and semiconducting carbon nanotubes can be analyzed by microscopic Raman spectroscopy and ultraviolet-visible near-infrared absorptiometry.

The dispersion liquid after the above cutting and dispersion step, and before the separation step may be subjected to centrifugation treatment to remove the bundles, amorphous carbon, metal impurities, and the like in the carbon nanotube dispersion liquid. The centrifugal acceleration may be appropriately adjusted, and is preferably 10000×g to 500000×g, more preferably 50000×g to 300000×g, and optionally 100000×g to 300000×g. The centrifugation time is preferably 0.5 hours to 12 hours, and more preferably 1 to 3 hours. The centrifugation temperature may be appropriately adjusted, and is preferably 4° C. to room temperature, and more preferably 10° C. to room temperature.

The concentration of the surfactant in the carbon nanotube dispersion liquid after separation which is used for the application may be appropriately controlled. The concentration of the surfactant in the carbon nanotube dispersion liquid is preferably from the critical micelle concentration to about 5% by mass, more preferably, 0.001% by mass to 3% by mass, and particularly preferably 0.01 to 1% by mass to suppress the reaggregation after application and the like.

The semiconducting carbon nanotube dispersion liquid obtained through the aforementioned steps is applied on a predetermined base material (such as a substrate and a heat insulating layer described later) and dried, and then a heat treatment is optionally performed, so that a carbon nanotube layer is formed.

The method for applying the semiconducting carbon nanotube dispersion liquid to a predetermined base material is not particularly limited, and examples thereof include dropping method, spin coating, printing, inkjet, spray coating, dip coating, and the like. From the viewpoint of reducing the manufacturing cost, a printing method is preferred. The printing methods can include application (dispenser, inkjet or the like), transferring (microcontact print, gravure printing, or the like) and the like.

The semiconducting carbon nanotubes dispersion liquid applied on a desired base material may be subjected to a heat treatment to remove the surfactant and the solvent. The temperature of the heat treatment may be appropriately set as long as it is equal to or higher than the decomposition temperature of the surfactant, and it is preferably 150 to 500° C., and more preferably 200 to 500° C., for example 200 to 400° C. A temperature of 200° C. or more is preferred because the remaining of the decomposition product of the surfactant can be easily suppressed. A temperature of 500° C. or less, for example 400° C. or less is preferred because the change in the quality of the substrate or other components can be suppressed. Also, the decomposition of carbon nanotubes, the change in size, the leaving of functional groups, and the like can be suppressed.

### (Negative Thermal Expansion Material)

In an embodiment, the bolometer films can comprise a negative thermal expansion material in addition to the carbon nanotubes.

The bolometer film according to the present embodiment is a carbon nanotube composite material in which a negative thermal expansion material is dispersed in a carbon nanotube aggregate having a three-dimensional mesh structure that forms a network structure formed of dispersed carbon nanotubes intertwined with each other into an aggregate. In such a three-dimensional electrically conductive network formed of carbon nanotubes, the carbon nanotubes are not necessarily all connected to each other to contribute to electric conductivity in the bolometer material, but part of the carbon nanotubes does not contribute to the electrical conduction mechanism. These unconnected carbon nanotubes build a new electrically conductive path resulting from the effect of reduction in the volume of the negative thermal expansion material exhibited by an increase in temperature. Or, the effect of reduction in the volume further increases the contact area between the carbon nanotubes, and moreover, the number of electrically conductive paths also increases. As a result, a larger increase in current occurs as the temperature increases, resulting in an improvement in a TCR value. That is, the negative thermal expansion material mixed with the semiconducting carbon nanotubes shrinks as the temperature rises, creating an additional network of carbon nanotubes previously separate from each other, resulting in an increase in the number of electrically conductive paths, whereby a greater amount of current flows. Furthermore, in an embodiment, using a negative thermal expansion material having resistance greater than that of the semiconducting carbon nanotubes allows more efficient formation of electrically conductive paths formed of the semiconducting carbon nanotubes.

In the present specification, the negative thermal expansion material means a material that has a negative coefficient of thermal expansion and contracts as the temperature rises. Examples of the negative thermal expansion material include a material having a coefficient of linear thermal expansion ΔL/L ((length after expansion−length before expansion)/length before expansion) per temperature difference of 1K preferably ranging from −1×10⁻⁶/K to −1×10⁻³/K, more preferably from −1×10⁻⁵/K to −1×10⁻³/K, in any temperature range from −100 to +200° C., for example, the range from −100 to +100° C., preferably in the temperature range over which the bolometer is used, for example, at least in the range from −50 to 100° C.

The coefficient of thermal expansion can be measured in accordance, for example, with JIS Z 2285 (method for measuring coefficient of linear expansion of metallic materials) or JIS R 1618 (method for measuring thermal expansion of fine ceramics based on thermo-mechanical analysis).

In an embodiment, the negative thermal expansion material is preferably a material that exhibits sufficient negative thermal expansion in the environment in which the bolometer is used. The temperatures of the environment in which the bolometer is used range, for example, from −350° C. to 100° C., preferably from −40° C. to 80° C., more preferably in some cases from 20° C. to 30° C., for example, from 21° C. to 30° C.

The humidity in the environment in which the bolometer is used, for example, in a case where the bolometer is used in a structure in which the bolometer part is exposed to the atmosphere, may be the ambient humidity, preferably, for example, 75% RH or lower. When the bolometer is vacuum-packaged or used in a structure in which the package is filled with an inert gas, the humidity is preferably, for example, 5% RH or lower, and may not fall within the range described above depending on the degree of vacuum and other factors. From the viewpoint of long-term stability of the device, lower humidity is preferable, so that the lower limit is not limited to a specific value in either case, and the humidity is 0% RH or higher, for example, higher than 0% RH.

The resistivity of the negative thermal expansion material described above is not limited to a specific value, and can range from 10⁻¹ Ωcm, for example, from 1 Ωcm to 10⁸ Ωcm, preferably from 10 Ωcm to 10⁸ Ωcm, more preferably from 10² Ωcm to 10⁷ Ωcm, in any temperature range from −100 to +100° C., preferably at the temperature at which the bolometer is used, for example, room temperature (about 23° C.). The resistivity can be measured in accordance with standard methods, for example, JIS K 7194 and JIS K 6911.

In the present specification, the negative thermal expansion material may include oxides, nitrides, sulphides or multi-element compounds containing one or two or more of Li, Al, Fe, Ni, Co, Mn, Bi, La, Cu, Sn, Zn, V, Zr, Pb, Sm, Y, W, Si, P, Ru, Ti, Ge, Ca, Ga, Cr, Cd, but not limited thereto. A mixture of two or more compounds may be used.

The negative thermal expansion material may include, but not limited thereto, vanadium oxides, β-eucryptite, bismuth-nickel oxides, zirconium tungstate, ruthenium oxides, manganese nitrides, lead titanate, samarium monosulphide and others (including those in which one or more of the elements of these compounds have been replaced by the above elements). For example, LiAlSiO₄, ZrW₂O₈, Zr₂WO₄(PO₄)₂, BiNi_{0.85}Fe_{0.15}O₃, Bi_{0.95}La_{0.05}NiO₃, Pb_{0.76}La_{0.04}Bi_{0.20}VO₃, Sm_{0.78}Y_{0.22}S, Cu_{1.8}Zn_{0.2}V₂O₇, Cu₂V₂O₇, 0.4PbTiO₃-0.6BiFeO₃, MnCo_{0.98}Cr_{0.02}Ge, Ca₂RuO_{3.74}, Mn₃Ga_{0.7}Ge_{0.3}N_{0.88}C_{0.12}, Cd(CN)₂-xCCl₄, LaFe_{10.5}Co_{1.0}Si_{1.5}, Ca₂RuO₄, Mn_{3.27}Zn_{0.45}Sn_{0.28}N, Mn₃Ga_{0.9}Sn_{0.1}N_{0.9}, Mn₃ZnN are suitable.

In one embodiment, oxides, nitrides, and sulphides are preferable among the negative thermal expansion materials, from the view point of ease of synthesis and availability.

In the present specification, the size of the negative thermal expansion material can be selected as appropriate. Preferably, it is 10 nm to 100 μm, more preferably 15 nm to 10 μm, and in some cases, it is also preferred to be from 50 nm to 5 μm.

The form of the negative thermal expansion material is not particularly limited, but may be, for example, spherical, needle, rod, plate, fibre, scale and the like, with spherical being preferred in terms of film formability.

The amount of negative thermal expansion material in the bolometer film can be selected as appropriate, but it is preferable that it is contained in an amount of 1 to 99% by mass, based on the total mass of the bolometer film, with 1 to 70% by mass being more preferable, for example, 1 to 50% by mass, in some cases 10 to 50% by mass, and optionally 40% by mass or less may also be preferred.

In addition to the carbon nanotubes and the negative thermal expansion material as an optional component, the bolometer film may also comprise a binder and, if desired, other components, but it is preferred that the total mass of the carbon nanotubes and the negative thermal expansion material is 70% by mass or more, more preferably 90% by mass or more, and even more preferably 95% by mass or more, based on the mass of the bolometer film.

The bolometer film comprising carbon nanotubes and negative thermal expansion materials can be produced by using a dispersion liquid in which a carbon nanotube dispersion is added with the negative thermal expansion materials and, if necessary, binding agents and the like in the above-described method of producing a bolometer film using a carbon nanotube dispersion.

### (Substrate)

The substrate may be either a flexible substrate or a rigid substrate, and may be appropriately selected, and those in which at least the element forming surface has insulating property or semiconducting property are preferred. For examples, inorganic materials such as Si, SiO₂-coated Si, SiO₂, SiN, glass and the like, and organic materials such as polymers, resins, plastics, for examples, parylene, polyimide, polyethylene, polypropylene, polystyrene, polyvinyl chloride, polyethylene terephthalate, acrylonitrile styrene resin, acrylonitrile butadiene styrene resin, fluororesin, methacrylic resin, polycarbonate and the like, but is not limited thereto.

### (Manufacturing Method of Bolometer Type Infrared Detector)

The bolometer type infrared detector of this embodiment can be manufactured, for example, as follows. A dispersion liquid containing semiconducting carbon nanotubes is applied onto a substrate, dried, and heat-treated. These operations form a bolometer film layer on the substrate. Thereafter, two contact electrodes (first and second electrodes), spaced by 50 μm to each other, are formed on the bolometer film layer by vapor deposition, sputtering, coating, or the like.

The bolometer type infrared detector of this embodiment can be also manufactured as follows for example. The surface of SiO₂-coated Si serving as a substrate is sequentially washed with acetone, isopropyl alcohol, and water, and is then subjected to oxygen plasma treatment to remove the organics and the like on the surface. The substrate is immersed in an aqueous 3-aminopropyltriethoxysilane (APTES) solution, dried, and then, a dispersion liquid of semiconducting carbon nanotubes that is dispersed in a polyoxyethylene alkyl ether solution such as polyoxyethylene (100) stearyl ether or polyoxyethylene (23) lauryl ether, which is a nonionic surfactant, is applied on the substrate and dried. The nonionic surfactant and the like are removed by heating the substrate in an air atmosphere at 200° C. As a result of these procedures, a thin layer of bolometer film is formed on the substrate. Thereafter, the first and the second electrodes spaced by 50 μm distance to each other are formed on the thin layer of bolometer film by gold evaporation. An acrylic resin (PMMA) solution is applied to the region between the electrodes on the layer of bolometer film formed to form a protective layer made of PMMA. Thereafter, the entire substrate is subjected to oxygen plasma treatment to remove the excess carbon nanotubes and the like on the region other than the bolometer film. Excess solvents, impurities, and the like are removed by heating in an air atmosphere at 200° C.

The resulting bolometer type infrared detector shown in FIG. 1 detects temperature using the temperature dependence of electrical resistance due to light irradiation. Therefore, even in other frequency regions, if the temperature changes due to light irradiation, it can be similarly used, and for example, the terahertz region can be detected. In addition, the detection of the change in electrical resistance caused by temperature change can also be performed not only by the structure of FIG. 1, but also by providing a gate electrode to form a field effect transistor and thereby amplifying the change in resistance value.

Although the basic configuration of the bolometer type infrared detector of this embodiment has been described above, any element (device) structure and array structure that can be used for infrared detectors can be applied without particular limitations to the bolometer type infrared detector of this embodiment. Examples of suitable element structures and array structures are described below, but the bolometer type infrared detector of this embodiment is not limited to these.

### [1] MEMS Type Device Structure

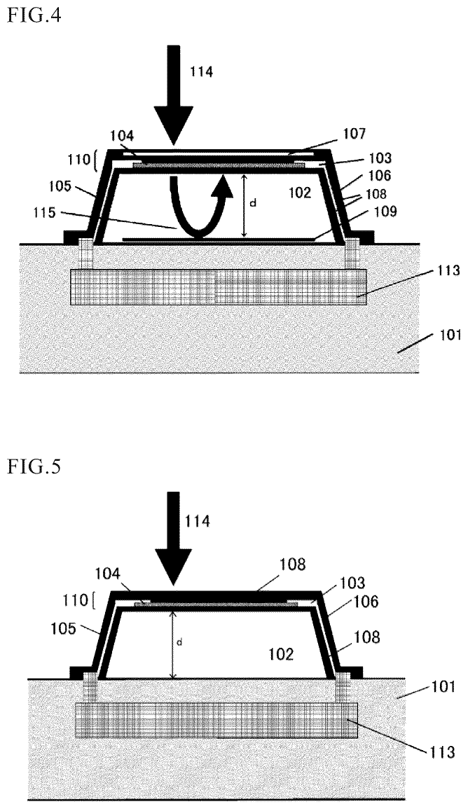

FIGS. 4 and 5 are vertical cross-sectional views of an element (device) of the bolometer infrared detector of this embodiment. This structure has an infrared detection unit (light receiving unit) 110 that is provided on a substrate (silicon substrate or the like) 101 on which a readout circuit 113 is formed such that the infrared detection unit is separated from the substrate 101 by a gap 102 with supporting legs 106 as supports. When the infrared rays 114 are irradiated, the bolometer film 104 of the infrared detector 110 is heated. The temperature change at this time is detected as a resistance change. In this embodiment, by using an alloy composed of two or more metals for at least one of the contact electrodes 103 connected to the bolometer film, a high TCR can be achieved, and the detection sensitivity can be enhanced.

As shown in FIG. 4, the bolometer type infrared detector of this embodiment may also be provided with a light reflecting layer 109 in order to increase the absorption rate of infrared rays. The infrared light 115 which has been transmitted without being completely absorbed by the bolometer film 104 is reflected and allowed incident on the bolometer film again. In addition, as shown in FIG. 4, an infrared absorption layer 107 may be provided directly above the bolometer film, or an infrared absorption structure 107 (not shown) called Hisashi (eaves) may be further provided to efficiently absorb the infrared ray incident on the pixels.

### [1-1] Components of Bolometer Element

Hereinafter, elements constituting the MEMS-type element (device) according to the present embodiment will be described individually in detail.

For substrate 101, contact electrode 103 and bolometer film 104, those described above for substrate 1, bolometer film 3 and contact electrodes 2 and 4 can be used. Other components are described below.

### (Gap)

In the bolometer type infrared detector of the present embodiment, a gap 102 is provided between the infrared detection unit 110 comprising the above-described bolometer film 104 and the substrate 101. In a bolometer equipped with a light reflecting layer 109 as shown in FIG. 4, the height d of the gap is preferably determined in consideration of the wavelength of infrared rays to be absorbed. In contrast, the bolometer comprising no infrared reflecting layer as shown in FIG. 5, the gap height d can be set to a desired value without considering the wavelength of the infrared ray to absorb. From the viewpoint of ease of fabrication, it is preferable to set the gap height d to 0.5 μm or more. The gap height d represents the distance from the top surface of the substrate 101 (or the top surface of the insulating protective film etc., if any, on the substrate) to the bottom surface of the infrared detection unit 110.

The insulation between the infrared detection unit and the substrate can also be improved by vacuum packaging the entire element and keeping the gap 102 in vacuum.

### (Infrared Absorbing Structure)

In the bolometer type infrared detector of the present embodiment, an infrared absorbing structure may be provided.

For example, an infrared absorbing structure 107 in a form of “eave” can be provided in order to efficiently absorb the incident infrared rays and further increase the fill factor. An example of such a structure includes those consisting of SiN, but is not limited thereto, and any structure used in the art can be used without a particular limitation.

Also, as shown in FIG. 4, an infrared absorbing layer 107 may be provided above the bolometer film 104, namely, on the side from which infrared rays are incident. The infrared absorbing layer can be provided directly on the bolometer film 104, or can be provided on a protection layer described later.

The thickness of the infrared absorbing layer depends on its material, and for example, may be from 50 nm to 1 μm.

In a case where an infrared absorbing layer 107 is provided directly on the bolometer film 104, the example thereof includes, but not limited thereto, a coating film of polyimide and the like. An example of the infrared absorbing layer 107 to be provided on a protection layer includes, but not limited thereto, a thin film of silicon nitrate and the like.

### (Light Reflection Layer)

In the bolometer type infrared detector of the present embodiment, a light reflection layer 109 may be provided between the bolometer film 104 and the substrate 101, for example, on the substrate 101 as shown in FIG. 4. For the light reflection layer 109, any materials that can be used in a bolometer can be used without limitation, and such materials generally include metals such as gold, silver, aluminium and the like.

When the light reflection layer 109 is provided as shown in FIG. 4, the distance d between the light reflection layer 109 and the bolometer film 104, that is, the height of the gap 102 is determined as d=λ/4 by considering the wavelength λ of the infrared rays to be absorbed.

A bolometer film containing semiconducting carbon nanotubes according to the present embodiment has a higher infrared absorptance than conventional bolometer films. Therefore, the light reflection layer and the infrared absorbing layer are not necessarily provided, and thus, one or both of these structural elements may be omitted. This allows more simplified device structures, leading to a reduction of manufacturing process cost.

### (Protection Layer)

In the bolometer type infrared detector of the present embodiment, as shown in FIG. 4 and FIG. 5, a protection layer 108 is preferably present on the bolometer film 104, and on and beneath the wiring 105. The protection layer can serve as an insulating protection layer, and when the protection layer is provided on the above side of the bolometer film, it also has effects of suppressing doping to carbon nanotubes due to the absorption of oxygen or the like, and of increasing the infrared absorption rate, which is because not only the bolometer but also the protection layer absorbs infrared ray.

The protective layer 108 can be made of without restriction any material used as a protective layer in a bolometer, and is preferably a material having high transparency in the range of infrared wavelengths to be detected. Examples of the material include, but not limited to, silicon nitride film, silicon oxide film, resins used in a heat insulating layer described later, such as parylene, as well as PMMA, PMMA anisole, and other acrylic resins, epoxy resins, and Teflon (Trade Mark). The thickness of the protective layer can, for example, range from 5 nm to 50 nm depending on the material.

### [1-2] Array Structure

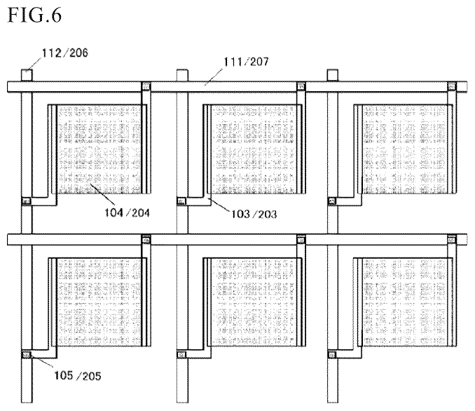

Although a bolometer of a single cell (single element) is shown in the above embodiment, a bolometer array can be made by arranging a plurality of elements in an array configuration. FIG. 6 is a plan view showing a bolometer array in which the sensor cells of FIGS. 4, 5 are arranged in an array configuration. A two-dimensional image sensor can be configured by connecting contact electrodes 103 of each element to a plurality of column wirings 112 for each column via contacts 105, and connecting to a plurality of row wirings 111 for each row via contacts 105. In such a structure, electrical signals are given to the row wiring 111 and the column wiring 112 corresponding to each cell, and then the resistance change of the cell is read out. An infrared image sensor is obtained by sequentially reading out the resistance changes of all cells.

### [1-3] Structure and Manufacturing Method of Bolometer Element (Device) and Bolometer Array

As a method of forming a bolometer array of this embodiment, manufacturing processes commonly used for manufacturing bolometers can be used without limitation, except that a carbon nanotube layer including semiconducting carbon nanotubes is used for the bolometer layer and at least one of the electrodes are formed of an alloy consisting two or more metals.

For the fabrication of the elements as shown in FIGS. 4 and 5, a silicon MEMS (Micro Electro Mechanical Systems) process is usually used. In the MEMS process, on a semiconductor substrate 101, first, a readout circuit constituted with a CMOS transistor and the like is formed, then an interlayer insulating film is formed thereon by the CVD method, and further, a metal light reflecting layer 109, an interlayer insulating film, and a sacrificial layer are formed thereon. After that, a protective insulating film of a silicon nitride film is formed by a CVD method, and contact electrodes 103 using an alloy of two or more kinds of metals according to this embodiment is formed thereon. Thereafter, a bolometer film 104 connected to the contact electrodes 103 and a second silicon nitride film 108 are formed. Finally, the sacrificial layer is removed by etching to form the gap 102 and obtain a cell with a diaphragm structure. The carbon nanotube film 104 is preferably formed by a printing method as described above, and the thickness and the density thereof are, for example, the thickness of 100 nm and the density of 1.1 g/cm³, respectively.

When an infrared absorbing layer 107 is provided in addition to the above components, it may be formed on the above bolometer film 104 or on a silicon nitrate film using a printing method or the like, or an infrared absorbing layer formed in advance may be layered.

It is also desirable to apply a transistor array to the bolometer array of the present embodiment. The application of a transistor array is advantageous in that, for example, it makes a high-speed scanning possible. The form of the transistor array is not limited, and any form used in the art can be applied without a particular limitation, for example, by building in the transistor array under the photosensitive area.

### [2] Printed-Type Device Structure

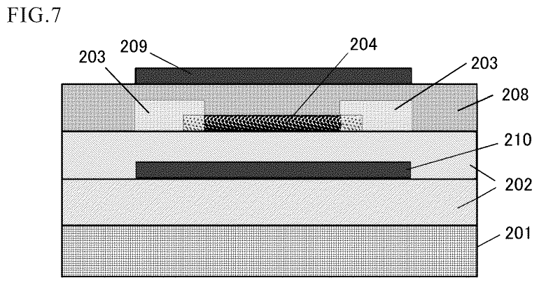

FIG. 7 is a vertical cross-sectional view of the element of the bolometer type infrared detector of this embodiment. In this structure, a heat insulating layer (parylene layer or the like) 202 is provided on a substrate (polyimide substrate or the like) 201, and a bolometer film (carbon nanotube film) 204 is provided on the heat insulating layer 202. Such a bolometer type infrared detector detects the intensity of infrared rays by reading the resistance change from the electrodes due to the temperature rise of the bolometer film. In this embodiment, by forming at least one of the contact electrodes 203 connected to the bolometer film 204 with an alloy of two or more metals, a high TCR can be achieved and the detection sensitivity can be enhanced.

In the bolometer type infrared detector of the present embodiment, the bolometer film 204 and the substrate 201 are thermally separated by the heat insulating layer 202, which prevents heat from escaping from the bolometer film 204 and improves detection sensitivity. Furthermore, it is advantageous in that the structure is simpler than the structure of a bolometer of a diaphragm-type structure having a gap between the substrate 201 and the bolometer film 204, and in that the vacuum packaging to evacuate the gap is not required.

Furthermore, it is also advantageous in that, since these bolometer film 204 and heat insulating layer 202 can be fabricated using printing technology, the manufacturing cost can be lowered as compared to the case of using the MEMS process.

### [2-1] Elements (Components) of Bolometer Element

Hereinafter, elements (components) constituting the bolometer element (device) according to the present embodiment will be each described in detail.

For substrate 201, contact electrode 203 and bolometer film 204. those described above for substrate 1, bolometer film 3 and contact electrodes 2 and 4 can be used. Other constituting elements will be described below.

### (Heat Insulating Layer)

The heat insulating layer 202 is a layer interrupting the heat transmission from the bolometer film 204 to the substrate 201. In the conventional bolometers, a gap is provided to serve as a structure interrupting the heat transmission from a bolometer film to a substrate, and complicated production processes are required to form such a gap. However, since the heat insulating layer in the present embodiment can be formed using a printing process and the like, and complicated production processes are thus not required. In addition, while in the conventional bolometers, the entire element is need to be vacuum packaged in order to keep the gap in vacuum, the bolometer of the present embodiment has an advantage of not requiring such vacuum packaging.

A resin component with a low heat conductivity is preferably used for the heat insulating layer. The heat conductivity of the resin component to be used for the heat insulating layer is lower than the heat conductivity of the substrate 201, and for example, is in the range of 0.02 to 0.3 (W/mK), preferably 0.05 to 0.15 (W/mK). Examples of such resin component include parylene, but not limited thereto. Parylene is a generic term for paraxylene-based polymers, and has a structure in which benzene rings are linked via CH₂. The examples of parylene include those formed from dimers represented by the following formula:

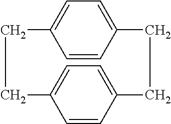 [SMILES: c1cc2ccc1CCc1ccc(cc1)CC2]

(In the formula, at least one hydrogen atom of at least one benzene ring may be substituted with a halogen atom. Halogen includes fluorine (F), chlorine (Cl), bromine (Br), iodine (I), and is preferably chlorine).

Parylene includes parylene N, parylene C, parylene D, parylene HT and the like, and among them, parylene C (heat conductivity: 0.084 (W/mK)) having the lowest heat conductivity is suitable.

The thickness of the heat insulating layer can be appropriately set in considering the heat conductivity of the component to use, and in a case of using parylene C for example, it is preferably in the range of 5 μm to 50 μm, and more preferably in the range of 10 μm to 20 μm.

### (Infrared Absorbing Layer)

In the bolometer type infrared detector of the present embodiment, as shown in FIG. 7, an infrared absorbing layer 209 may be provided above the bolometer film 204, namely, on the side from which infrared rays are incident. The infrared absorbing layer can be provided on the protection layer 208 described later, or directly on the bolometer film 204.

When the infrared absorption layer 209 is provided as shown in FIG. 7, for example, the infrared absorption layer exemplified in the above MEMS type device can be used.

### (Light Reflection Layer)

In the bolometer type infrared detector of the present embodiment, as shown in FIG. 7, a light reflecting layer (infrared reflecting layer) 210 may be provided between the bolometer film 204 and the substrate 201 in order to absorb infrared rays that enter from above and pass through the bolometer film without being absorbed. As the light reflecting layer 210, for example, those exemplified in the MEMS type device can be used.

A bolometer film containing semiconducting carbon nanotubes of the present embodiment has a higher infrared absorptance than conventional bolometer films. Therefore, since it is not always necessary to provide a light reflecting layer or an infrared absorbing layer, one or both of these constituent elements can be omitted. This makes it possible to further simplify the device structure and reduce the cost of the manufacturing process.

### (Protection Layer)

In the bolometer type infrared detector of this embodiment, it is preferable that a protective layer 208 exists on the bolometer film 204 as shown in FIG.

As the protective layer 208, for example, those exemplified in the MEMS type device can be used.

### [2-2] Array Structure

A printed element can also be formed into a bolometer array by arranging a plurality of elements in an array, as explained for the MEMS type device structure with reference to FIG. 6.

### [2-3] Method for Manufacturing Bolometer

The method for manufacturing the bolometer according to the present embodiment is not particularly limited and any method used for manufacturing a bolometer can be appropriately employed. From the view point of simplifying the manufacturing processes and lowering the cost, it is preferred to form a heat insulating layer and a bolometer film on a desired substrate using a printing method or the like, but it is not necessarily limited to the printing method.

### (1) Bolometer Film

A bolometer film can be formed by coating the dispersion liquid containing the semiconducting carbon nanotubes obtained by the above-described process on the above-described heat insulating layer and drying it. Also, a bolometer film formed by applying a dispersion containing carbon nanotubes on a desired substrate may be laminated on the above-described heat insulating layer. For film formation of this case, the same steps and conditions as those for film formation on the above-described substrate may be applied.

### (2) Heat Insulating Layer

The manufacturing method of the heat insulating layer is not particularly limited as long as the method can produce the heat insulating layer described above. For example, when a parylene film is used as the heat insulating layer, the parylene film can be formed by coating a desired area with parylene using a vacuum vapor deposition apparatus. Specifically, when solid dimer is heated under vacuum, it vaporizes to become dimer gas. This gas is thermally decomposed and the dimer is cleaved to a monomer form. In the vapor deposition chamber at room temperature, this monomer gas polymerizes on all surfaces to form a thin, transparent polymer film.

If necessary, pre-treatment of the substrate, cleaning of the substrate, and masking of the areas that should not be deposited may be performed before the vapor deposition process is performed.

### (3) Structure and Manufacturing Method of Bolometer Array

An example of the structure and the manufacturing method of a bolometer array will be described with reference to the figures, but the structure and the manufacturing method of the bolometer array are not limited thereto.

### EXAMPLE 1

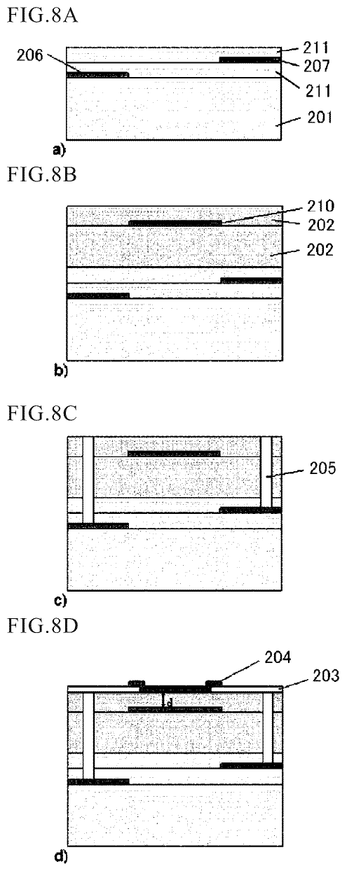

In FIG. 8A, an aluminum film (1000 Å) is vapor-deposited on substrate 201 through a metal mask to form column wiring 206. Then, insulating film 211 is formed by applying polyimide. Row wiring 207 is formed thereon in a same manner as the column wiring. Further, the second insulating film 211 is formed by applying polyimide thereon.

Next, as shown in FIG. 8B, as heat insulating layer 202, a parylene film is formed with, for example, a thickness of about 20 μm by vapor deposition. Parylene is usually in a dimer state, and is heated to about 700° C. in a vapor deposition apparatus to becomes a monomer state, and then becomes a polymer state after being vapor-deposited on the substrate.

Then, as shown in FIG. 8C, contact holes 205 are opened by lithography and dry etching.

Then, as shown in FIG. 8D, contact electrodes 203 according to the present embodiment are formed, which are connected to row wirings and column wirings through contact holes 205. The electrode 203 can be formed by vapor deposition, sputtering, printing, or the like. The contact electrode 203 may be formed after the bolometer film 204 is formed.

Thereafter, bolometer film 204 is formed. Bolometer film 204 is preferably formed by a printing method, for example, by applying the carbon nanotube dispersion liquid described above by a dispenser apparatus. Here, the thickness and the density of the bolometer film are, for example, the thickness of 100 nm and the density of 1.1 g/cm³, respectively.

When providing a light reflecting layer, after forming a parylene film as the heat insulating layer 202, aluminium (having thickness of 1000 Å) is formed thereon as the light reflecting layer 210 by vapor deposition, and the second heat insulating layer 202 is formed thereon by vapor deposition of parylene to a thickness of about 2.5 μm (distance d).

If a protective film 208 is to be provided in addition to the above components, for example, a protection layer can be formed by applying a resin solution used for the protection layer on the formed bolometer film 204. Thereafter, the entire substrate may be subjected to an oxygen plasma treatment to remove excess carbon nanotube and the like present in the areas other than bolometer film 204.

If an infrared absorbing layer 209 is to be provided in addition to the above components, it may be formed on the above bolometer film 204 or protective film 208 using a printing method or the like, or an infrared absorbing layer formed in advance may be layered or transferred.

In the following example, examples of a method for manufacturing a bolometer that does not have a light reflecting layer, an infrared absorbing layer, a protective layer, and the like is shown. However, it is naturally possible to include steps of forming a light reflecting layer, an infrared absorbing layer, a protective layer, and the like in these examples.

### EXAMPLE 2

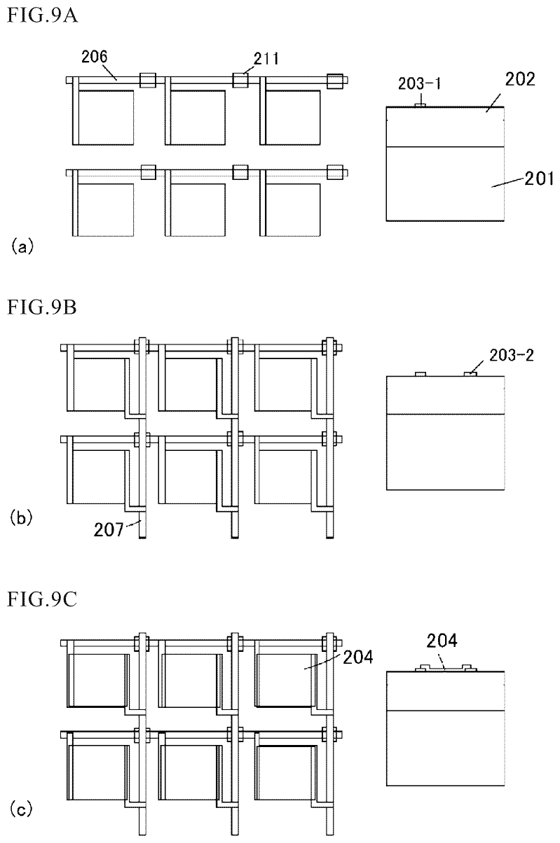

Another example will be explained with reference to FIGS. 9A and 9B.

First, as shown in FIG. 9A, heat insulating layer 202 is formed on substrate 201, and first electrode 203-1 and column wiring 206 are formed thereon.

Next, insulating film 211 is formed to insulate a part of row wiring 206 that intersects with a row wiring in a later process. A method of forming the insulating film includes coating polyimide to form a film using a printing method.

Next, as shown in FIG. 9B, second electrode 203-2 and row wiring 207 are formed in a same manner as the first electrode and the column wiring.

Herein, at least one of the first electrode and the second electrode is provided using the alloy consisting of two or more metals according to the present embodiment, and may be formed by evaporation or sputtering method. The column wiring and the row wiring may be made of the same material as the first electrode and the second electrode, respectively, or may be made of a different material. However, it is more preferable to use the material used for the wiring layer of the CMOS process. If the column wiring and the row wiring are made of the same material as the first electrode and the second electrode, respectively, they may be formed at the same time as the first electrode and the second electrode.

Next, as shown in FIG. 9C, bolometer film 204 connected with the first and second electrodes is formed.

According to such a method, a bolometer array can be manufactured using a printing process and the like without performing a contact formation, which enables further cost reduction.

### EXAMPLE 3

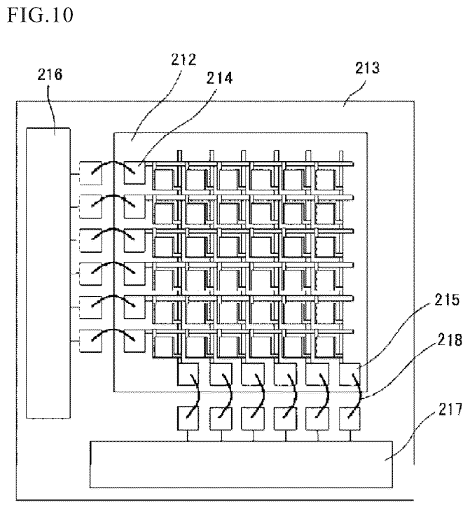

Another example will be explained with reference to FIG. 10. In the bolometer array of FIG. 10, a bolometer array is formed on first substrate 212, such as a resin substrate, and a readout circuit is formed on second substrate 213, which is a semiconductor substrate, using an ordinary silicon CMOS process (not shown). An insulating layer is formed on the readout circuit, and the first substrate is attached on the second substrate. The bolometer array of the present embodiment can be formed by electrically connecting column terminals 214 and row terminals 215 of the first substrate to the terminals leading to column selecting circuit 216 and row selecting circuit 217 in the readout circuit on the second substrate using bonding wires 218 or the like.

### EXAMPLE 4

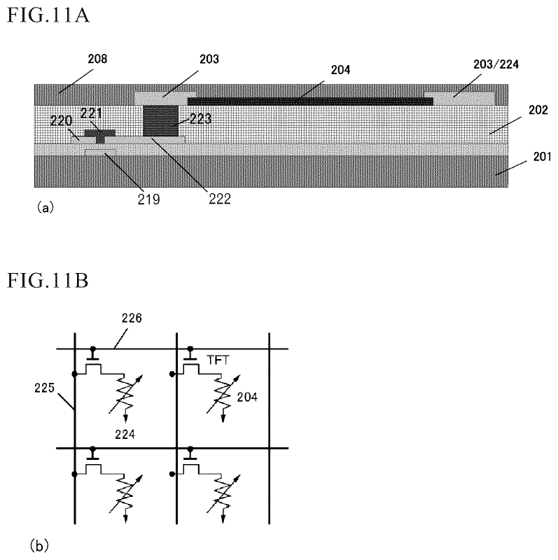

Another example will be explained with reference to FIG. 11.

A TFT (thin-film transistor) array is also preferably applied to the array sensor according to the present embodiment. The application of a TFT array makes possible high-speed scanning. The form of the TFT array is not particularly limited, and one example thereof is shown in FIGS. 9A and 9B. In the TFT array shown in FIG. 9A, gate electrode 219 is placed on substrate 201, and source electrode 220 and drain electrode 122 are formed on the upper layer thereof with an insulating layer therebetween. Heat insulating layer 102, carbon nanotube film 204, and protective film 208 are formed on the upper layer thereof. Drain electrode 122 is connected to pixel electrode 203, which is formed in contact with the carbon nanotube film 204, through via 223 that extends through heat insulating layer 102. The other electrode 203 is connected to common electrode 224. The two-dimensional arrangement of the pixel circuit of this TFT array is shown in FIG. 9B.

Some or all of the above embodiments may also be described as in the Supplementary notes below, but the disclosures of the present application are not limited to the appendix below.

### [Supplementary Note 1]

A bolometer type infrared detector comprising:

a substrate,

a bolometer film comprising semiconducting carbon nanotubes, and

two electrodes spaced from each other and connected to the bolometer film, wherein at least one of the two electrodes is formed of a metal alloy comprising at least two metals selected from the group consisting of Li, Be, Al, Ti, V, Cr, Mn, Fe, Co, Ni, Cu, Zn, Y, Zr, Nb, Mo, Ru, Rh, Pd, Ag, In, Sn, Sb, Ba, La, Hf, Ta, Ir, Pt, Au, and Bi.

### [Supplementary Note 2]

The bolometer type infrared detector according to Supplementary note 1, wherein the two electrodes are formed of a same alloy.

### [Supplementary Note 3]

The bolometer type infrared detector according to Supplementary note 1, wherein the two electrodes are formed of alloys different from each other.

### [Supplementary Note 4]

The bolometer type infrared detector according to Supplementary notes 1 to 3, wherein

at least one of the two electrodes is formed of a metal alloy selected from the group consisting of

(a) metal alloys of:

Al and

(i) one or more metals selected from the group consisting of Pd, Pt, and Au,

(ii) one or more metals selected from the group consisting of Fe, Co, Ni, Cu, Mo, Ru, Rh, Pd, Ag, Sb, Ir, Pt, and Au,

(iii) one or more metals selected from the group consisting of Be, Ti, V, Cr, Mn, Fe, Co, Ni, Cu, Zn, Zr, Nb, Ag, In, Sn, Sb, Hf, Ta, and Bi, or

(iv) one or more metals selected from the group consisting of Li, Y, Zr, Ba, La, Hf, and Ta;

(b) metal alloys of:

Cu and

(i) one or more metals selected from the group consisting of Pd, Pt, and Au,

(ii) one or more metals selected from the group consisting of Be, Al, Ti, V, Cr, Mn, Fe, Co, Ni, Zn, Zr, Nb, Mo, Ru, Rh, Pd, Ag, In, Sn, Sb, Hf, Ta, Ir, Pt, Au, and Bi,

(iii) one or more metals selected from the group consisting of Li, Al, Mn, Zn, Y, Nb, In, Ba, La, and Ta, or

(iv) one or more metals selected from the group consisting of Li and Ba;

(c) metal alloys of:

Ag and,

(i) one or more metals selected from the group consisting of Pd, Pt, and Au,

(ii) one or more metals selected from the group consisting of Be, Al, Ti, V, Cr, Mn, Fe, Co, Ni, Cu, Zn, Zr, Nb, Mo, Ru, Rh, Pd, In, Sn, Sb, Hf, Ta, Ir, Pt, Au, and Bi,

(iii) one or more metals selected from the group consisting of Li, Be, Al, Ti, Mn, Zn, Y, Zr, Ba, La, Hf, and Ta, or

(iv) one or more metals selected from the group consisting of Li and Ba; and

(d) metal alloys of:

Au and

(i) one or more metals selected from the group consisting of Be, Al, Ti, V, Cr, Mn, Fe, Co, Ni, Cu, Zn, Zr, Nb, Mo, Ru, Rh, Pd, Ag, In, Sn, Sb, Ta, Ir, and Pt,

(ii) one or more metals selected from the group consisting of Li, Be, Al, V, Cr, Mn, Fe, Ni, Cu, Zn, Y, Nb, Mo, Rh, Ag, In, and Ba, or

(iii) one or more metals selected from the group consisting of Li and Ba.

### [Supplementary Note 5]

The bolometer type infrared detector according to Supplementary notes 1 to 4, wherein the bolometer film is a composite material comprising a carbon nanotube and a negative thermal expansion material.

### [Supplementary Note 6]

The bolometer type infrared detector according to Supplementary note 5, wherein the negative thermal expansion material is an oxide, a nitride, a sulfide, or a multi-element compound, comprising one or more element selected from the group consisting of Li, Al, Fe, Ni, Co, Mn, Bi, La, Cu, Sn, Zn, V, Zr, Pb, Sm, Y, W, Si, P, Ru, Ti, Ge, Ca, Ga, Cr, and Cd.

### [Supplementary Note 7]

The bolometer type infrared detector according to Supplementary notes 1 to 6, wherein the bolometer film comprises semiconducting carbon nanotubes in an amount of 90% by mass or more based on a total amount of the semiconducting carbon nanotubes.

### [Supplementary Note 8]

A method of manufacturing a bolometer type infrared detector, the method comprising:

providing a substrate,

forming a bolometer film comprising semiconducting carbon nanotubes, and

forming two electrodes so that the two electrodes are spaced from each other and connected to the bolometer film, wherein at least one of the two electrodes is formed of a metal alloy comprising at least two metals selected from the group consisting of Li, Be, Al, Ti, V, Cr, Mn, Fe, Co, Ni, Cu, Zn, Y, Zr, Nb, Mo, Ru, Rh, Pd, Ag, In, Sn, Sb, Ba, La, Hf, Ta, Ir, Pt, Au, and Bi.

### EXPLANATION OF REFERENCE

1 Substrate
2 Contact electrode
3 Bolometer film (carbon nanotube film)
4 Contact electrode
101 Substrate
102 Gap
103 Electrode
104 Bolometer film
105 Wiring
106 Supporting leg
107 Infrared absorbing layer/Infrared absorbing structure
108 Protection layer (insulating protection layer)
109 Light reflecting layer (infrared reflecting layer)
110 Infrared detection part
111 Row wiring
112 Column wiring
113 Readout circuit
114 incident light
115 Light transmitted through a bolometer film
201 Substrate
202 Heat insulating layer
203 Electrode
204 Bolometer film
205 Contact
206 Column wiring
207 Row wiring
208 Protection layer
209 Infrared absorbing layer
210 Light reflection layer
211 Insulating film
212 First substrate
213 Second substrate
214 Column terminal
215 Row terminal
216 Column selecting circuit
217 Row selecting circuit
218 Bonding wire
219 Gate electrode
220 Source electrode
221 Semiconductor
222 Drain electrode
223 Via
224 Common electrode
225 Source line
226 Gate line

1. A bolometer type infrared detector comprising:
a substrate,
a bolometer film comprising semiconducting carbon nanotubes, and
two electrodes spaced from each other and connected to the bolometer film, wherein at least one of the two electrodes is formed of a metal alloy comprising at least two metals selected from the group consisting of Li, Be, Al, Ti, V, Cr, Mn, Fe, Co, Ni, Cu, Zn, Y, Zr, Nb, Mo, Ru, Rh, Pd, Ag, In, Sn, Sb, Ba, La, Hf, Ta, Ir, Pt, Au, and Bi.

2. The bolometer type infrared detector according to claim 1, wherein the two electrodes are formed of a same alloy.

3. The bolometer type infrared detector according to claim 1, wherein the two electrodes are formed of alloys different from each other.

4. The bolometer type infrared detector according to claim 1, wherein at least one of the two electrodes is formed of a metal alloy selected from the group consisting of
(a) metal alloys of:
Al and
(i) one or more metals selected from the group consisting of Pd, Pt, and Au,
(ii) one or more metals selected from the group consisting of Fe, Co, Ni, Cu, Mo, Ru, Rh, Pd, Ag, Sb, Ir, Pt, and Au,
(iii) one or more metals selected from the group consisting of Be, Ti, V, Cr, Mn, Fe, Co, Ni, Cu, Zn, Zr, Nb, Ag, In, Sn, Sb, Hf, Ta, and Bi, or
(iv) one or more metals selected from the group consisting of Li, Y, Zr, Ba, La, Hf, and Ta;
(b) metal alloys of:
Cu and
(i) one or more metals selected from the group consisting of Pd, Pt, and Au,
(ii) one or more metals selected from the group consisting of Be, Al, Ti, V, Cr, Mn, Fe, Co, Ni, Zn, Zr, Nb, Mo, Ru, Rh, Pd, Ag, In, Sn, Sb, Hf, Ta, Ir, Pt, Au, and Bi,
(iii) one or more metals selected from the group consisting of Li, Al, Mn, Zn, Y, Nb, In, Ba, La, and Ta, or
(iv) one or more metals selected from the group consisting of Li and Ba;
(c) metal alloys of:
Ag and,
(i) one or more metals selected from the group consisting of Pd, Pt, and Au,
(ii) one or more metals selected from the group consisting of Be, Al, Ti, V, Cr, Mn, Fe, Co, Ni, Cu, Zn, Zr, Nb, Mo, Ru, Rh, Pd, In, Sn, Sb, Hf, Ta, Ir, Pt, Au, and Bi,
(iii) one or more metals selected from the group consisting of Li, Be, Al, Ti, Mn, Zn, Y, Zr, Ba, La, Hf, and Ta, or
(iv) one or more metals selected from the group consisting of Li and Ba; and
(d) metal alloys of:
Au and
(i) one or more metals selected from the group consisting of Be, Al, Ti, V, Cr, Mn, Fe, Co, Ni, Cu, Zn, Zr, Nb, Mo, Ru, Rh, Pd, Ag, In, Sn, Sb, Ta, Ir, and Pt,
(ii) one or more metals selected from the group consisting of Li, Be, Al, V, Cr, Mn, Fe, Ni, Cu, Zn, Y, Nb, Mo, Rh, Ag, In, and Ba, or
(iii) one or more metals selected from the group consisting of Li and Ba.

5. The bolometer type infrared detector according to claim 1, wherein the bolometer film is a composite material comprising a carbon nanotube and a negative thermal expansion material.

6. The bolometer type infrared detector according to claim 5, wherein the negative thermal expansion material is an oxides, a nitride, a sulfide, or a multi-element compound, each comprising one or more element selected from the group consisting of , Li, Al, Fe, Ni, Co, Mn, Bi, La, Cu, Sn, Zn, V, Zr, Pb, Sm, Y, W, Si, P, Ru, Ti, Ge, Ca, Ga, Cr, and Cd.

7. The bolometer type infrared detector according to claim 1, wherein the bolometer film comprises semiconducting carbon nanotubes in an amount of 90% by mass or more based on a total amount of the semiconducting carbon nanotubes.

8. A method of manufacturing a bolometer type infrared detector, the method comprising:
providing a substrate,
forming a bolometer film comprising semiconducting carbon nanotubes, and
forming two electrodes so that the two electrodes are spaced from each other and connected to the bolometer film, wherein at least one of the two electrodes is formed of a metal alloy comprising at least two metals selected from the group consisting of Li, Be, Al, Ti, V, Cr, Mn, Fe, Co, Ni, Cu, Zn, Y, Zr, Nb, Mo, Ru, Rh, Pd, Ag, In, Sn, Sb, Ba, La, Hf, Ta, Ir, Pt, Au, and Bi.
